(19) United States
(12) Patent Application Publication
(10) Pub. No.: US 2011/0074048 A1
(43) Pub. Date: Mar. 31, 2011

(54) SEMICONDUCTOR DEVICE AND METHOD OF MANUFACTURING THE SAME

(75) Inventors: Toshihiko Shibita, Osaka (JP); Takayuki Yoshida, Shiga (JP); Hiroaki Fujimoto, Osaka (JP)

(73) Assignee: PANASONIC CORPORATION, Osaka (JP)

(21) Appl. No.: 12/964,253

(22) Filed: Dec. 9, 2010

Related U.S. Application Data
(63) Continuation of application No. PCT/JP2009/002584, filed on Jun. 9, 2009.

(30) Foreign Application Priority Data
Jun. 11, 2008 (JP) 2008-152347

(51) Int. Cl. H01L 23/28; H01L 21/56

(52) U.S. Cl. 257/787; 438/127; 257/E21.502; 257/E23.116

(57) ABSTRACT

A semiconductor device of the present invention includes: a base material (5); a semiconductor element (2) mounted on the base material (5); a solder resist (11a) covering a prescribed region of the base material (5); and a molding resin body (3) integrally covering the semiconductor element (2) and a part of the solder resist (11a). The solder resist (11a) has a recessed portion (16) at the bottom of the outer circumference of the molding resin body (3). The molding resin body (3) is partially embedded in the recessed portion (16).

### FIELD OF THE INVENTION

The present invention relates to a semiconductor device and a method of manufacturing the same.

### BACKGROUND OF THE INVENTION

In a typical semiconductor device, a semiconductor element mounted on the surface of a substrate is covered with a molding resin body. The molding resin body is typically formed as follows: the substrate on which the semiconductor element is mounted is clamped with dies and then molding resin is injected into a die cavity.

In the related art, it has been proposed to taper or round the sides of a die cavity to prevent a die from damaging a substrate during the formation of a molding resin body (e.g., see Japanese Patent Laid-Open No. 11-67801). To be specific, the sides of the die cavity are tapered or rounded and thus a stress concentration is reduced on a boundary portion between the side of the die cavity and the substrate contact surface of the die, so that damage is prevented on the substrate. Hereinafter, the boundary portion between the side of the die cavity and the substrate contact surface of the die will be called the inner circumference of the die.

As has been discussed, in the related art, the sides of the die cavity are tapered or rounded to prevent the die from damaging the substrate. However, in the presence of wiring under the inner circumference of the die, even the tapered or rounded sides of the die cavity may damage the substrate.

Specifically, a typical substrate includes wiring formed on the surface of a base material, and a solder resist covering the surface of the base material and the wiring. The wiring is not easily compressed by a clamping load applied from a die, unlike the solder resist. Thus in the presence of wiring under the inner circumference of the die, damage such as cracks like grooves may occur on the solder resist covering the wiring.

The present invention has been devised in view of the problem. An object of the present invention is to provide a semiconductor device and a method of manufacturing the same which can suppress the possibility of damage on a substrate when a molding resin body is formed using dies.

### DISCLOSURE OF THE INVENTION

A semiconductor device of the present invention includes: a base material; a semiconductor element mounted on the base material; a solder resist covering a region outside the mounted semiconductor element on the base material; and a molding resin body covering the semiconductor element and a part of the solder resist together, wherein the solder resist has a recessed portion at the bottom of the outer circumference of the molding resin body and the molding resin body is partially embedded in the recessed portion.

The semiconductor device of the present invention, wherein the recessed portion may have the bottom away from the bottom of the solder resist.

The semiconductor device of the present invention, wherein the solder resist may have a multilayer structure of at least two layers. In this case, the recessed portion may be formed by partially removing the upper layer of the solder resist. Moreover, in this case, the recessed portion may be formed by cylindrically removing a part of the upper layer of the solder resist.

The semiconductor device of the present invention, wherein the molding resin body may contain filler. In this case, the recessed portion may have dimensions smaller than a value indicating the maximum particle size of the filler.

A method of manufacturing a semiconductor device according to the present invention, in which during the formation of a molding resin body covering a semiconductor element mounted on a substrate, the substrate on which the semiconductor element is mounted is clamped with dies and then molding resin is injected into the cavity of the die, the method including the step of, when the substrate is clamped with the dies, causing the inner circumstance of the die to face a recessed portion formed in advance on a solder resist covering the substrate.

The method of manufacturing a semiconductor device according to the present invention, wherein the solder resist may have a multilayer structure of at least two layers. In this case, the recessed portion may be formed by partially removing the upper layer of the solder resist. Further, in this case, the recessed portion may be a through hole formed on the upper layer of the solder resist.

The method of manufacturing a semiconductor device according to the present invention, wherein the recessed portion may have dimensions smaller than a value indicating the maximum particle size of filler contained in the molding resin body.

A preferred embodiment of the present invention can suppress the possibility of damage on a substrate when a molding resin body is formed using dies. In other words, a solder resist has a recessed portion at the bottom of the outer circumference of the molding resin body and the molding resin body is partially embedded in the recessed portion. In order to manufacture a semiconductor device configured thus, the inner circumference of the die has to face the recessed portion. With this configuration, a clamping load from the inner circumference of the die is not directly applied to the solder resist, thereby suppressing damage on the substrate.

### BRIEF DESCRIPTION OF THE DRAWINGS

FIG. 1 is a perspective view showing a semiconductor device according to an embodiment of the present invention;

FIG. 2 is a sectional view showing the semiconductor device according to the embodiment of the present invention;

FIG. 3 is an enlarged sectional view showing part A of FIG. 2;

FIG. 4 is an enlarged sectional view for explaining the dimensions of a recessed portion of the semiconductor device according to the embodiment of the present invention;

FIG. 5 is an enlarged sectional view showing another example of the recessed portion of the semiconductor device according to the embodiment of the present invention;

FIG. 6 is a process sectional view for explaining a part of the process of a manufacturing method of the semiconductor device according to the embodiment of the present invention;

FIG. 7 is a process sectional view for explaining a part of the process of the manufacturing method of the semiconductor device according to the embodiment of the present invention; and

FIG. 8 is an enlarged view showing part B of FIG. 7.

### DESCRIPTION OF THE EMBODIMENT

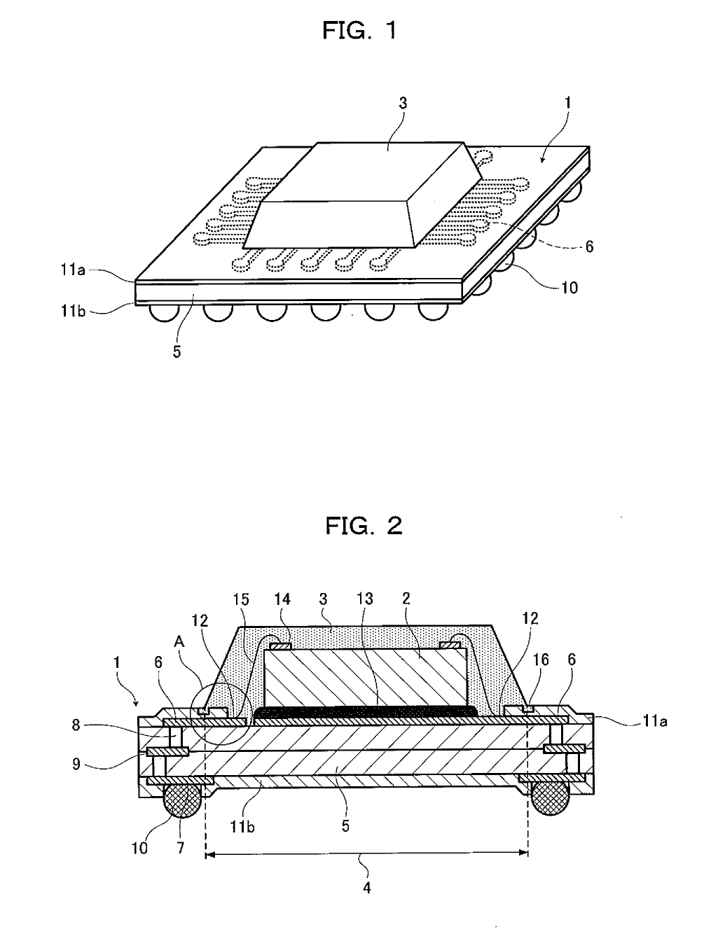

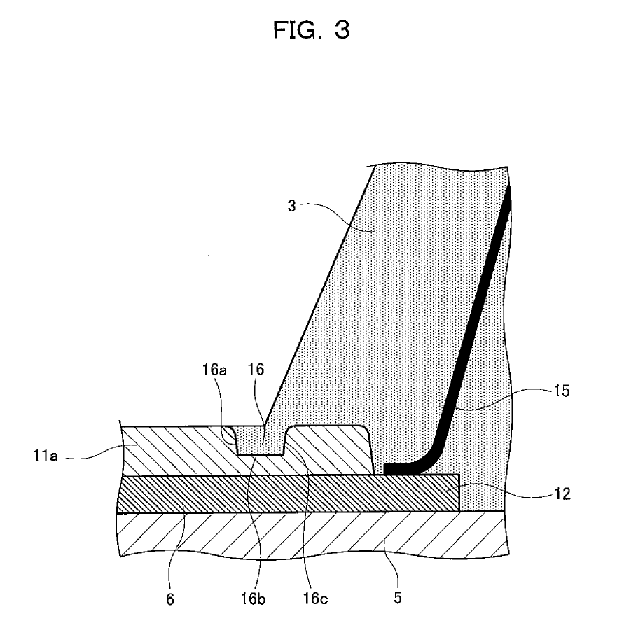

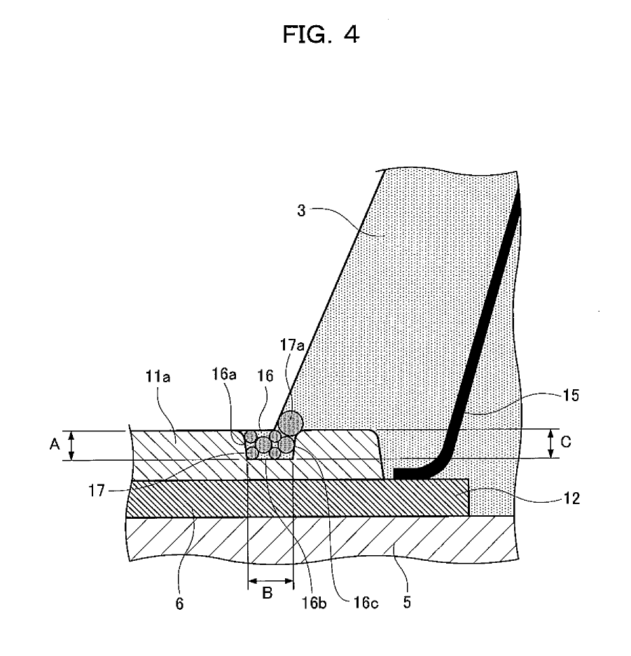

An embodiment of the present invention will be described below in accordance with the accompanying drawings. The aforementioned members will be indicated by the same reference numerals and the explanation thereof is omitted when necessary. FIG. 1 is a perspective view showing a semiconductor device according to the embodiment of the present invention. FIG. 2 is a sectional view showing the semiconductor device according to the embodiment of the present invention. FIG. 3 is an enlarged sectional view showing the semiconductor device according to the embodiment of the present invention. Enlarged in FIG. 3 is part A of FIG. 2.

As shown in FIGS. 1 and 2, the semiconductor device includes a two-layer substrate 1, a semiconductor element 2 mounted on a semiconductor mounting part 4 of the substrate 1, and a molding resin body 3 covering the semiconductor element 2. The semiconductor mounting part 4 is a predetermined region covered with the molding resin body 3. Although the two-layer substrate will be described in the present embodiment, as a matter of course, the present invention can be implemented using a single-layer substrate or substrates having three or more layers.

The substrate 1 includes a base material 5, a plurality of wires 6 formed on the top surface of the base material 5, and a plurality of connection terminals 7 formed on the underside of the base material 5. In the base material 5, vias 8 and inner wires 9 are formed. The vias 8 and the inner wires 9 connect the wires 6 on the top surface of the substrate 1 and the connection terminals 7 on the underside of the substrate 1. Further, external connection terminals 10 shaped like balls are connected to the connection terminals 7.

On the top surface and the underside of the substrate 1, a solder resist 11a and a solder resist lib are formed, respectively. To be specific, the solder resist 11a on the top surface of the substrate 1 is formed over a region outside the semiconductor mounting part 4 and on the outer circumference of the semiconductor mounting part 4. The solder resist 11b on the underside of the substrate 1 is formed in a region other than the region of the external connection terminals 10.

The wires 6 are formed from the inside to the outside of the substrate 1. The wires 6 are each made up of a covered portion that is covered with the solder resist 11a and an uncovered portion that is not covered with the solder resist 11a. The uncovered portions act as connection terminals 12. In other words, the connection terminals 12 are formed in the semiconductor mounting part 4 and the wires 6 have the covered portions connected to the connection terminals 12 and formed from the inside to the outside of the semiconductor mounting part 4.

The semiconductor element 2 is formed in the semiconductor mounting part 4. To be specific, the semiconductor element 2 is fixed on the substrate 1 with, e.g., an adhesive 13. Terminals 14 of the semiconductor element 2 and the connection terminals 12 on the top surface of the substrate 1 are electrically connected via thin metallic wires 15.

The molding resin body 3 integrally covers and resin-molds the semiconductor element 2, the solder resist 11a on the top surface of the substrate 1 and in the semiconductor mounting part 4, the connection terminals 12, and the thin metallic wires 15.

As shown in FIG. 3, on the solder resist 11a on the top surface of the substrate 1, a recessed portion 16 is formed at the bottom of the outer circumference of the molding resin body 3. The molding resin body 3 is partially embedded in the recessed portion 16. In this configuration, from the bottom of the outer circumference of the molding resin body 3, a region of the recessed portion 16 on the outer side of the base material 5 is formed larger than the other region of the recessed portion 16 on the inner side of the base material 5. Further, the upper corners of the recessed portion 16 are rounded in this configuration.

The molding resin body 3 is partially embedded in the recessed portion 16 thus, so that moisture or the like from the outside of the molding resin body 3 passes through a long path formed of an outer wall 16a, a bottom wall 16b, and an inner wall 16c of the recessed portion 16. Thus the moisture or the like hardly enters the semiconductor mounting part 4.

The dimensions of the recessed portion 16 will be discussed below. As shown in FIG. 4, dimension A of the outer wall 16a of the recessed portion 16 and dimension C of the inner wall 16c of the recessed portion 16 are preferably set at values smaller than the filler cut value of filler 17 mixed in the molding resin body 3. The filler cut value indicates the diameter of the largest filler particle 17a of the filler 17 mixed in the molding resin body 3. The dimensions of the recessed portion 16 contribute to the prevention of an outflow of the molding resin to the surface of the substrate. The dimension A of the outer wall 16a and the dimension C of the inner wall 16c do not need to be equal to each other. Moreover, dimension B of the bottom wall 16b of the recessed portion 16 may be any dimension as long as the molding resin can smoothly flow into the recessed portion 16 during the formation of the molding resin body 3. The dimension B is set relative to the dimension A of the outer wall 16a and the dimension C of the inner wall 16c.

The formation position and the cross-sectional shape of the recessed portion 16 are preferably set such that from the bottom of the outer circumference of the molding resin body 3, a region of the recessed portion 16 on the outer side of the substrate 1 is formed larger than the other region of the recessed portion 16 on the inner side of the substrate 1. With this configuration, the molding resin easily flows into the recessed portion 16 during the formation of the molding resin body 3. Thus the recessed portion 16 is more reliably filled with a part of the molding resin body 3. Further, the upper corners of the recessed portion 16 are preferably rounded. This configuration improves the strength of the recessed portion 16 against damage.

The recessed portion 16 can be formed by partially removing the upper layer of the solder resist 11a on the top surface of the substrate 1, the solder resist 11a having a multilayer structure of at least two layers. With this configuration, the underside of the recessed portion 16 is separated from the top surfaces of the wires 6, so that moisture or the like hardly enters the wires 6 from the recessed portion 16.

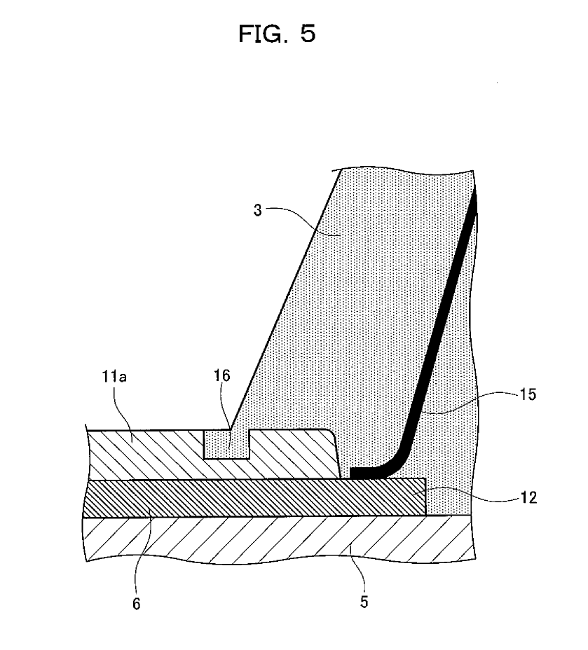

The following will describe another example of the recessed portion 16. As shown in FIG. 5, the recessed portion 16 may be cylindrical. The cylindrical recessed portion 16 can be formed by cylindrically removing a part of the upper layer of the solder resist 11a on the top surface of the substrate 1, the solder resist 11a having a multilayer structure of at least two layers. In other words, the recessed portion 16 may be a through hole formed on the upper layer of the solder resist 11a. The cylindrical recessed portion 16 formed thus can simplify processing conditions and processing control during the formation of the recessed portion 16.

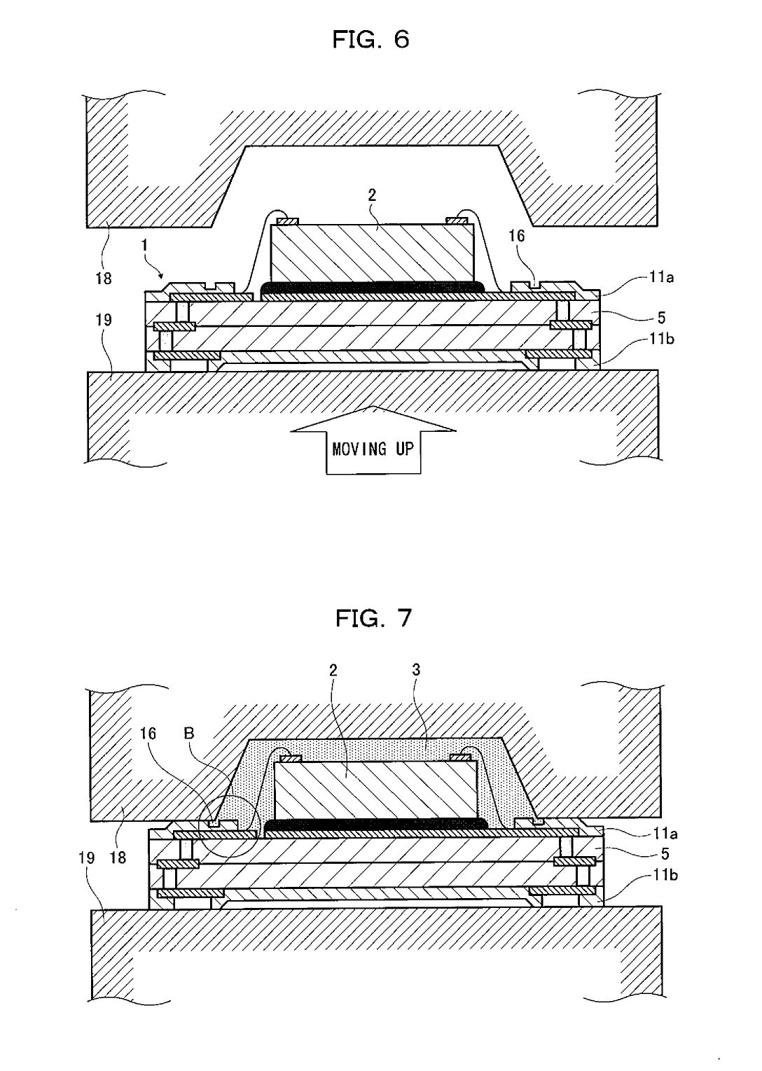

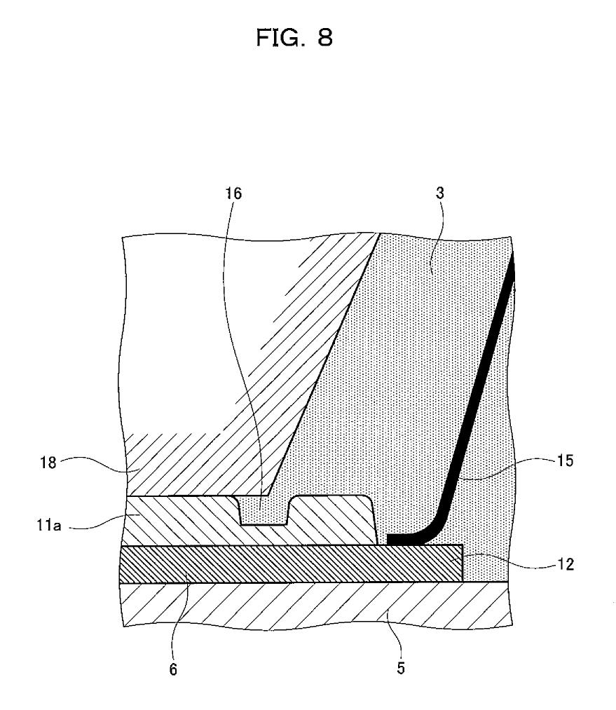

In the manufacturing process of the semiconductor device configured thus, a process of forming the molding resin body 3 will be discussed below. FIGS. 6 and 7 are process sectional views for explaining a method of manufacturing the semiconductor device according to the embodiment of the present invention. FIG. 8 is a process sectional view for explaining the method of manufacturing the semiconductor device according to the embodiment of the present invention. Enlarged in FIG. 8 is part B of FIG. 7.

As shown in FIGS. 6 and 7, the molding resin body 3 is formed by using an upper die 18 and a lower die 19. First, as shown in FIG. 6, the substrate 1 on which the semiconductor element 2 is mounted is placed on the lower die 19. Next, the lower die 19 moves up toward the upper die 18. The lower die 19 moves up until the semiconductor element 2 is accommodated in the cavity of the upper die 18 and the substrate 1 is clamped by the upper die 18 and the lower die 19 as shown in FIG. 7.

The position of the substrate 1 is set on the lower die 19 as follows: when the substrate 1 is clamped, as shown in FIG. 8, the inner circumference of the upper die 18, that is, a boundary portion between a side of the cavity of the upper die 18 and the contact surface of the upper die 18 with the substrate is opposed to the recessed portion 16 formed on the solder resist 11a on the substrate 1. With this configuration, a clamping load from the inner circumference of the upper die 18 is not directly applied to the solder resist 11a, thereby suppressing damage caused by the dies to the solder resist 11a and the base material 5.

Outside the recessed portion 16, a clamping load is applied from the upper die 18 to the solder resist 11a. However, the contact surface of the upper die 18 with the substrate is flat outside the recessed portion 16. Thus an extremely large clamping load is not applied outside the recessed portion 16, and the solder resist 11a and the base material 5 are not damaged outside the recessed portion 16.

The molding resin is injected into the cavity of the upper die 18 in a state in which the upper die 18 and the lower die 19 are set thus. At this point, conditions such as the feed rate and pressure of the molding resin are adjusted to allow the molding resin to flow into the recessed portion 16. Thus the molding resin body 3 is formed so as to integrally cover the semiconductor element 2, the solder resist 11a in the semiconductor mounting part 4, the connection terminals 12, and the thin metallic wires 15, and fill the recessed portion 16.

The recessed portion 16 may be integrally formed over the bottom of the outer circumference of the molding resin body 3 or multiple recessed portions 16 may be separately formed over the bottom of the outer circumference of the molding resin body 3.

The semiconductor device and the method of manufacturing the same according to the present invention can suppress the possibility of damage on the substrate when the molding resin body is formed using the dies, and thus the present invention is widely applicable to the configurations of semiconductor devices used for various kinds of electronic equipment.

What is claimed is:

1. A semiconductor device comprising:
a base material;
a semiconductor element mounted on the base material;
a solder resist covering a region outside the mounted semiconductor element on the base material; and
a molding resin body integrally covering the semiconductor element and a part of the solder resist, wherein the solder resist has at least a two-layer structure and has a recessed portion at a bottom of an outer circumference of the molding resin body, and the molding resin body is partially embedded in the recessed portion.

2. The semiconductor device according to claim 1, wherein the recessed portion has a bottom away from a bottom of a lower layer of the solder resist having the two-layer structure.

3. The semiconductor device according to claim 1, wherein the recessed portion is formed by partially removing an upper layer of the solder resist.

4. The semiconductor device according to claim 1, wherein the recessed portion is formed by cylindrically removing a part of an upper layer of the solder resist.

5. The semiconductor device according to claim 1, wherein the molding resin body contains filler and the recessed portion has dimensions smaller than a value indicating a maximum particle size of the filler.

6. A method of manufacturing a semiconductor device, in which during formation of a molding resin body covering a semiconductor element mounted on a substrate, the substrate on which the semiconductor element is mounted is clamped with dies and then molding resin is injected into a cavity of the die,
the method comprising the step of, when the substrate is clamped with the dies, causing an inner circumference of the die to face a recessed portion formed on an upper layer of a solder resist that covers the substrate and has at least a two-layer structure.

7. The method of manufacturing a semiconductor device according to claim 6, wherein the recessed portion is formed by partially removing the upper layer of the solder resist.

8. The method of manufacturing a semiconductor device according to claim 6, wherein the recessed portion is a through hole formed on the upper layer of the solder resist.

9. The method of manufacturing a semiconductor device according to claim 6, wherein the recessed portion has dimensions smaller than a value indicating a maximum particle size of filler contained in the molding resin body.

10. A semiconductor device comprising:
a base material;
a semiconductor element mounted on the base material;
a solder resist covering a region outside the mounted semiconductor element on the base material; and
a molding resin body integrally covering the semiconductor element and a part of the solder resist, wherein the solder resist has a recessed portion at a bottom of an outer circumference of the molding resin body such that the recessed portion has side walls and a bottom wall, the molding resin body is partially embedded in the recessed portion, and the bottom wall of the recessed portion is separated from a bottom of the solder resist.

11. The semiconductor device according to claim 10, wherein the solder resist has at least a two-layer structure and the recessed portion is formed by partially removing an upper layer of the solder resist.

12. A semiconductor device comprising:
a base material;
a semiconductor element mounted on the base material;
a solder resist covering a region outside the mounted semiconductor element on the base material; and
a molding resin body integrally covering the semiconductor element and a part of the solder resist,
wherein the solder resist has a recessed portion at a bottom of an outer circumference of the molding resin body,
the molding resin body is partially embedded in the recessed portion,
the molding resin body contains filler, and
the recessed portion has dimensions smaller than a value indicating a maximum particle size of the filler.

13. A method of manufacturing a semiconductor device, in which during formation of a molding resin body covering a semiconductor element mounted on a substrate, the substrate on which the semiconductor element is mounted is clamped with dies and then molding resin is injected into a cavity of the die,
the method comprising the step of, when the substrate is clamped with the dies, causing an inner circumference of the die to face a recessed portion formed in advance on a solder resist covering the substrate,
the recessed portion having dimensions smaller than a value indicating a maximum particle size of filler contained in the molding resin body.
